(19) United States
(12) Patent Application Publication
(10) Pub. No.: US 2007/0182491 A1
(43) Pub. Date: Aug. 9, 2007

(54) Wideband amplifying circuit having large degree of freedom in bias setting

(75) Inventor: Akihisa Iikura, Fukushima-ken (JP)

Correspondence Address: BEYER WEAVER LLP, P.O. BOX 70250, OAKLAND, CA, 94612-0250, US

(73) Assignee: ALPS ELECTRIC CO., LTD.

(21) Appl. No.: 11/654,830

(22) Filed: Jan. 17, 2007

(30) Foreign Application Priority Data
Feb. 8, 2006 (JP) 2006-030714

(51) Int. Cl. H03F 1/22

(52) U.S. Cl. 330/311

(57) ABSTRACT

A wideband amplifying circuit includes a first bipolar transistor in which an RF signal is input at an input terminal, a transistor output circuit connected to a collector of the first bipolar transistor, and a feedback circuit connected between the output terminal of the transistor output circuit and a base of the first bipolar transistor. The feedback circuit is formed by a series-connected circuit of a first resistor in which one terminal is connected to the input terminal of the first bipolar transistor, and a second resistor in which one terminal is connected to the output terminal of the transistor output circuit and the other terminal is connected to the other terminal of the first resistor, and a third resistor is provided between a connection point of the first resistor and the second resistor and the ground.

### BACKGROUND OF THE INVENTION

1. Field of the Invention

The present invention relates to a wideband amplifying circuit capable of amplifying a signal in a wideband.

2. Description of the Related Art

Conventionally, television receiving tuners have been used for receiving a television signal of a wideband. To amplify the received signal, wideband amplifying circuits have been used. In such conventional wideband amplifying circuits, generally, an output signal is taken out using an emitter follower circuit, for example, as disclosed in Japanese Unexamined Patent Application Publication No. 11-8517.

In the wideband amplifying circuit described in Japanese Unexamined Patent Application Publication No. 11-8517, to a base of a transistor for an amplifying circuit, an emitter (output terminal) of an emitter follower circuit is connected through a feedback circuit. To the feedback circuit, in addition to a feedback resistor, a diode is inserted for operation point adjustment of the transistor.

However, in the above-described known wideband amplifying circuit, since a voltage between terminals of the diode is a relatively large value of about 0.7 V and the value is constant, the degree of freedom in bias setting is small. Further, generally, since the diode has a frequency characteristic, if the diode is used in the wideband amplifying circuit, it can affect the frequency characteristic of the amplifying circuit and deteriorate the characteristic.

### SUMMARY OF THE INVENTION

The present invention has been made in view of the above and an object of the present invention is to provide a wideband amplifying circuit capable of improving a gain and a frequency characteristic while increasing the degree of freedom in bias setting.

A wideband amplifying circuit according to the present invention includes a first transistor in which an RF signal is input at an input terminal, a transistor output circuit connected to an output terminal of the first transistor, and a feedback circuit connected between the output terminal of the transistor output circuit and the input terminal of the first transistor. The feedback circuit is formed by a series-connected circuit including a first resistor in which one terminal is connected to the input terminal of the first transistor, and a second resistor in which one terminal is connected to the output terminal of the transistor output circuit and the other terminal is connected to the other terminal of the first resistor, and a third resistor is provided between a connection point of the first resistor and the second resistor and the ground.

According to this configuration, the feedback circuit is formed by the series-connected circuit of the first resistor and the second resistor, and as compared with the configuration in which the diode is provided in the feedback circuit for operation point adjustment, the degree of freedom in bias setting can be largely increased and by eliminating the diode having a frequency characteristic, the frequency characteristic can be improved.

The transistor output circuit can be formed by an emitter follower circuit formed by a second transistor. Moreover, the first transistor can be formed by connecting two bipolar transistors in cascade.

According to the present invention, in the wideband amplifying circuit, the first transistor, the transistor output circuit, the second resistor, and the third resistor are integrated on an integrated circuit, and the first resistor is mounted to the outside of the integrated circuit as an external resistor.

With this configuration, since the first resistor to be a feedback resistor is mounted to the outside of the integrated circuit, the feedback resistor can be adjusted outside of the integrated circuit, and performances corresponding to various applications can be implemented on single integrated circuit.

According to the present invention, while the degree of freedom in bias setting in a wideband amplifying circuit can be increased, a gain and a frequency characteristic can be improved.

### BRIEF DESCRIPTION OF THE DRAWINGS

FIG. 1 is a configurational view illustrating a wideband amplifying circuit according to an embodiment of the present invention;

FIG. 2A is a view illustrating a result of a simulation of each characteristic in the wideband amplifying circuit according to the embodiment of the present invention;

FIG. 2B is a view illustrating a result of a simulation of each characteristic in a comparative example in which a diode is inserted;

FIG. 2C is a view illustrating a result of a simulation of each characteristic in a comparative example in which a value of resistance is set to be zero; and

FIG. 3 is a configurational view illustrating a wideband amplifying circuit according to a modification of the embodiment of the present invention.

### DESCRIPTION OF THE PREFERRED EMBODIMENTS

Hereinafter, with reference to the attached drawings, an embodiment of the present invention will be described in detail.

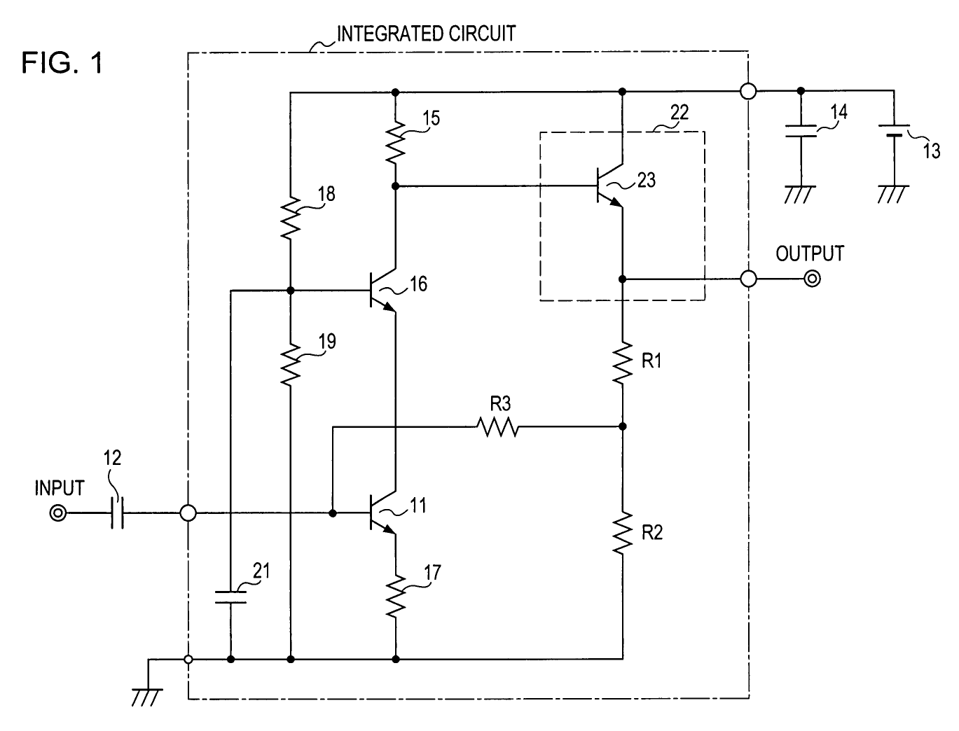

FIG. 1 is a configurational view illustrating a wideband amplifying circuit according to the embodiment of the present invention. As illustrated in the drawing, the wideband amplifying circuit according to this embodiment is formed as an integrated circuit. A base of a first bipolar transistor 11 forms an input terminal of the first transistor, and connected to an input terminal INPUT through a capacitor 12. To the outside of the integrated circuit, a direct-current power source 13 and a bypass capacitor 14 are provided. The cathode of the direct-current power source 13 and one electrode (nongrounded side) of the bypass capacitor 14 are connected with each other. The first bipolar transistor 11 and a second bipolar transistor 16 are connected in cascade and form a first transistor. A collector of the second bipolar transistor 16 is connected to the cathode of the direct-current power source 13 and an emitter of the first bipolar transistor 11 is grounded through a resistor 17.

To a base of the second bipolar transistor 16, an intermediate connection point of voltage dividing resistors 18 and 19 which are connected in series between the cathode of the direct-current power source 13 and the ground is connected. The intermediate connection point of the voltage dividing resistors 18 and 19 is grounded through a capacitor 21. By applying a predetermined bias voltage to the base of the second bipolar transistor 16, a collector to be an output terminal of the first bipolar transistor 11 is connected to an input terminal of a transistor output circuit 22 through between an emitter and the collector of the second bipolar transistor 16 in series.

The transistor output circuit 22 is formed by an emitter follower circuit with a third bipolar transistor 23. Specifically, a base of the third bipolar transistor 23 becomes an input terminal of the transistor output circuit 22, and an emitter of the third bipolar transistor 23 becomes an output terminal of the transistor output circuit 22. A collector of the third bipolar transistor 23 is connected to the cathode of the direct-current power source 13 and the emitter is grounded through a series-connected circuit of resistors R1 and R2. Accordingly, an output signal according to an RF signal input to the base of the third bipolar transistor 23 is taken out through the emitter follower circuit. The output signal taken out through the emitter follower circuit of the transistor output circuit 22 is output to the outside from an output terminal OUTPUT of the wideband amplifying circuit.

On the other hand, while the emitter of the third bipolar transistor 23 to be the output terminal of the transistor circuit 22 is grounded through the series-connected circuit of resistors R1 and R2, the emitter is connected to the base of the first bipolar transistor 11 via a feedback circuit formed by the resistor R1 and a resistor R3. That is, in this embodiment, the feedback circuit to feedback the output signal to the input terminal of the first transistor is formed by the series-connected circuit of the resistor R3 as a first resistor in which one terminal is connected to the base of the first bipolar transistor 11 and the resistor R1 as a second resistor in which one terminal is connected to the emitter of the third bipolar transistor 23 and the other terminal is connected to the other terminal of the resistor R3. The resistor R2 becomes a third resistor provided between a connection point of the resistors R1 and R3 and the ground.

Now, operation of the wideband amplifying circuit according to this embodiment will be described.

From the input terminal INPUT to the base of the first bipolar transistor 11, an RF signal is input. Since to the base of the second bipolar transistor 16, a predetermined voltage of a divided power supply voltage is applied, a collector current corresponding to the RF signal input to the base flows to the first bipolar transistor 11. That is, to the collector of the first bipolar transistor 11, the collector current which is an amplified input RF signal flows, and the current is input to the transistor output circuit 22 as an amplified output of the first bipolar transistor 11.

In the transistor output circuit 22, the input RF signal is supplied to the base of the third bipolar transistor 23, and an output signal according to the input RF signal is output from the emitter of the third bipolar transistor 23. The output signal thus taken out by the emitter follower circuit of the transistor output circuit 22 is input to the base of the first bipolar transistor 11 through the feedback circuit while output to the outside from the output terminal OUTPUT.

In this embodiment, since the feedback circuit to feedback the output signal of the transistor output circuit 22 to the base of the first bipolar transistor 11 is formed by the series circuit of the resistors R1 and R3, the degree of freedom of design is largely increased.

If to the emitter side of the emitter follower circuit of the transistor output circuit 22, instead of the resistor R1, a diode is provided or the resistor R1 is set to be zero, the degree of freedom decreases as described above. If the resistor R1 is replaced with the diode or the resistor R1 is set to be zero, while the value of the current flowing in the third bipolar transistor 23 is determined according to the value of the resistor R2, the base voltage of the first bipolar transistor 11 is determined depending on the value of the current flowing in the third bipolar transistor 23 and the resistor R2. Accordingly, while the base voltage of the first bipolar transistor 11 is maintained at a constant value by only adjusting the resistor R2, it is difficult to adjust the value of the current flowing to the emitter of the third bipolar transistor 23.

According to this embodiment, since the current flowing in the third bipolar transistor 23 is determined depending on the series connected resistors R1 and R2, while the base voltage of the first bipolar transistor 11 is maintained at the constant value, it is possible to adjust the value of current flowing in the third bipolar transistor 23 by the resistor R1. Further, since a feedback is given to the base of the first bipolar transistor 11 by the resistors R1 and R3, the amount of the feedback can be readily adjusted.

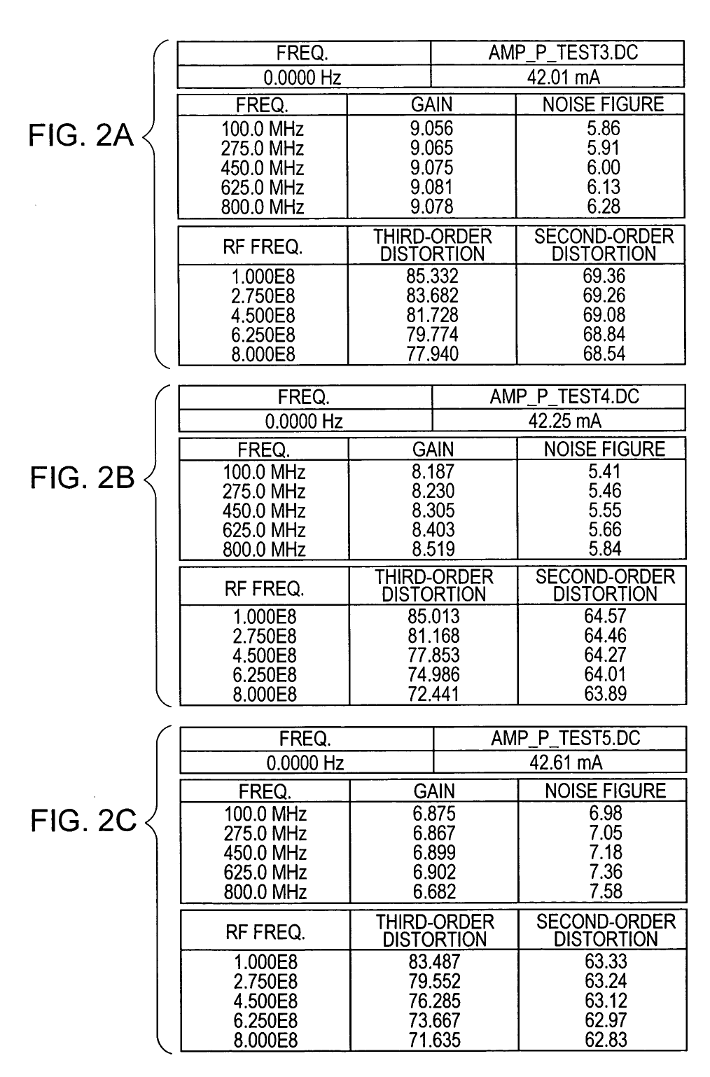

FIGS. 2A, 2B, and 2C illustrate results of simulations of gains, noise frequencies, third-order distortions, and second-order distortions under substantially similar current conditions with respect to three wideband amplifying circuits. In the drawings, values at five points ranging from 100 MHz to 800 MHz are illustrated. FIG. 2A illustrates a result of a simulation with respect to the wideband amplifying circuit according to the embodiment, FIG. 2B illustrates a result of a simulation in a comparative example in which a diode is inserted in place of the resistor R1 in the circuit illustrated in FIG. 1, and FIG. 2C illustrates a result of a simulation in a comparative example in which the resistor R1 is set to be zero in the circuit illustrated in FIG. 1.

Comparing the gains in the simulation results illustrated in FIGS. 2A, 2B, and 2C, in this embodiment, the gain is larger than those in the comparative examples of FIGS. 2B and 2C, and it is understood that the characteristic is improved in this aspect. With respect to the noise figures, the third-order distortions, and the second-order distortions, any large difference is not found.

As described above, according to this embodiment, since the feedback circuit to feedback the output signal of the transistor output circuit 22 to the input of the first bipolar transistor 11 is formed by the series circuit of the resistors R1 and R3, while the degree of freedom in design can be largely increased, a part of the characteristics can be improved. Further, since the diode for operation point adjustment of the first bipolar transistor 11 is eliminated, the disadvantage that the frequency characteristic of the diode deteriorates the frequency characteristic of the wideband amplifying circuit can be reduced, and accordingly, the improvement of the frequency characteristic in this aspect can be expected.

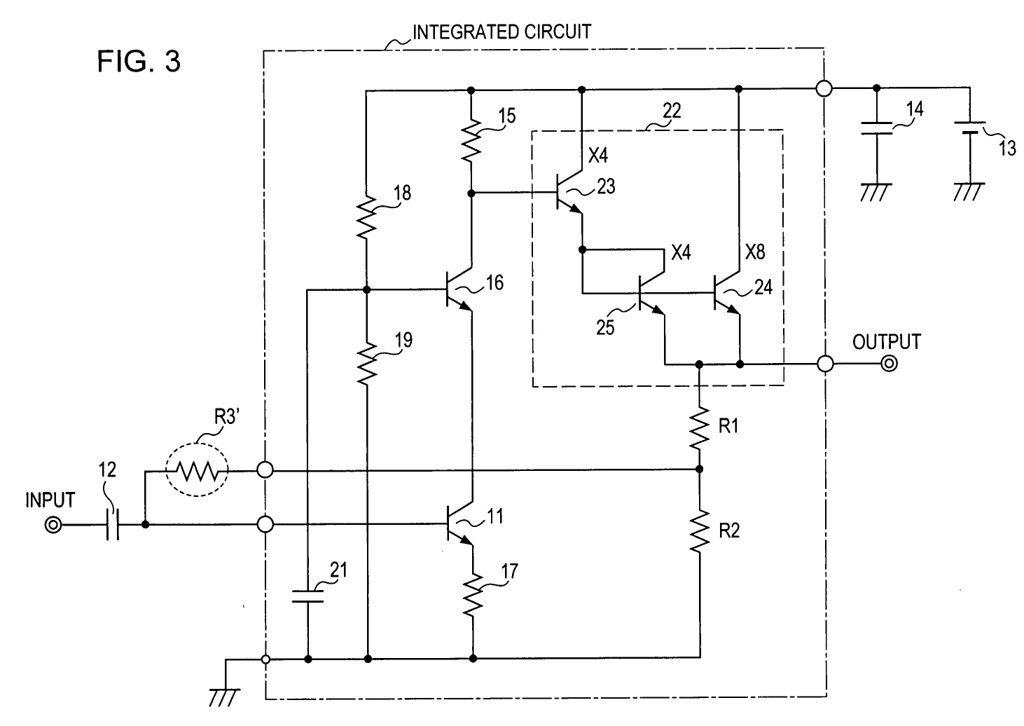

FIG. 3 is a configurational view illustrating a wideband amplifying circuit according to a modification of the above-described embodiment. In the modification illustrated in the drawing, while the resistor R3 in the feedback circuit is set outside of the integrated circuit as an external resistor R3′, the transistor output circuit 22 is formed by a FT doubler circuit. The other configurations are similar to those in the above-described embodiment illustrated in FIG. 1. In the FT doubler circuit, the third bipolar transistor 23 and a fourth bipolar transistor 24 are Darlington-connected, and between a base and an emitter of the fourth bipolar transistor 24, a diode-connected fifth bipolar transistor 25 is connected in parallel. The emitter of the fourth bipolar transistor 24 becomes an output terminal of the transistor output circuit 22.

Now, an operation of the wideband amplifying circuit according to the modification formed as described above will be described. From the input terminal INPUT of the wideband amplifying circuit to the base of the first bipolar transistor 11, an RF signal is input. To the first bipolar transistor 11, a collector current corresponding to the RF signal input to the base flows, and the current is supplied to the input terminal of the FT doubler circuit as an amplified output of the first bipolar transistor 11.

The FT doubler circuit (hereinafter, referred to as a FT doubler circuit 22) which forms the transistor output circuit 22 amplifies the input RF signal supplied to the base of the third bipolar transistor 23 from the first bipolar transistor 11 and outputs to the output terminal OUTPUT from the emitter of the fourth bipolar transistor 24.

In the wideband amplifying circuit according to this embodiment, by receiving the amplifying circuit output of a first stage by the FT doubler circuit 22 to be an amplifying circuit of a second stage, the FT doubler circuit 22 functions to shift the level of a bias. Generally, in the bipolar transistor, the voltage between the base and the emitter in operation is about from 0.7 V to 0.8 V. However, since the FT doubler circuit 22 shifts the level by the amount of two bipolar transistors, the bias decreases by about 1.7 V. Thus, the base voltage of the latter stage is decreased and the voltage between the collector and the emitter can be widely set, and the performance of the latter amplifying circuit can be improved. Further, as compared with the method of inserting the resistor to decrease the voltage, the loss is reduced, and as compared with the method of shutting the direct current component by capacity to give a voltage, the necessary area can be reduced, and accordingly, advantageous for integrated circuits.

Further, by receiving the amplifying circuit output of the first stage by the FT doubler circuit 22 to be the amplifying circuit of the second stage, the FT doubler circuit 22 functions as a buffer. That is, the FT doubler circuit 22 buffers effects to the former stage by change of output.

While the amplified RF signal output from the FT doubler circuit 22 is output to the outside from the output terminal OUTPUT, through a feedback resistor formed by a series-connected circuit of the resistor R1 and the external resistor R3′, is fed back to the base of the first bipolar transistor 11. By feeding back the amplified RF signal from the FT doubler circuit 22 to the first bipolar transistor 11 which is the amplifying circuit of the first stage, the distortion characteristic especially in a high-frequency band can be improved. Further, with the improvement of the distortion characteristic of the wideband amplifying circuit, a good characteristic can be ensured at a value of current lower than that in a conventional wideband amplifying circuit, and current consumption can be reduced.

Further, according to this modification, since one of resistors forming the feedback circuit is formed by the external resistor R3′ which is provided to the outside of the integrated circuit, the feedback resistor can be externally adjusted and performances corresponding to various applications can be implemented on single integrated circuit. For example, by adjusting the feedback resistor, the performances of the gain, the noise figure, and the distortion can be adjusted to a desired value respectively. Further, only one IC pin to be a terminal is to be added to provide the external resistor R3′, the cost is prevented from increasing.

What is claimed is:

1. A wideband amplifying circuit comprising:
a first transistor in which an RF signal is input at an input terminal;
a transistor output circuit connected to an output terminal of the first transistor; and
a feedback circuit connected between the output terminal of the transistor output circuit and the input terminal of the first transistor;
wherein the feedback circuit comprises a series-connected circuit comprising a first resistor in which one terminal is connected to the input terminal of the first transistor, and a second resistor in which one terminal is connected to the output terminal of the transistor output circuit and the other terminal is connected to the other terminal of the first resistor; and
a third resistor is provided between a connection point of the first resistor and the second resistor and the ground.

2. The wideband amplifying circuit according to claim 1, wherein the transistor output circuit comprises an emitter follower circuit comprising a second transistor.

3. The wideband amplifying circuit according to claim 1, wherein the first transistor comprises cascade-connected two bipolar transistors.

4. The wideband amplifying circuit according to claim 1, wherein the first transistor, the transistor output circuit, the second resistor, and the third resistor are integrated on an integrated circuit; and
the first resistor is mounted to the outside of the integrated circuit as an external resistor.
